(19) United States
(12) Patent Application Publication
(10) Pub. No.: US 2012/0054583 A1
(43) Pub. Date: Mar. 1, 2012

(54) METHOD AND SYSTEM OF SUB-PACKET ERROR CORRECTION

(75) Inventors: Sung I. Park, Irvine, CA (US); Jiwon Hahn, Fullerton, CA (US); Erwin Ward Bathrick, III, Yorba Linda, CA (US)

(73) Assignee: Raytheon Company, Waltham, MA (US)

(21) Appl. No.: 12/869,895

(22) Filed: Aug. 27, 2010

(51) Int. Cl. H03M 13/05; G06F 11/10

(52) U.S. Cl. 714/776; 714/E11.032

(57) ABSTRACT

In one aspect, a sub-packet error correction method includes receiving a data packet, segregating the data packet into sub-packets, and encoding the sub-packets using an erasure code for transmission over a network, and receiving the encoded sub-packets, decoding the sub-packets, and combining the decoded sub-packets to reconstruct the data packet. In some embodiments, the data packet is received at a first proxy server for transmission over a lossy network, the encoded sub-packets received at a second proxy server over the lossy network.

### FIELD OF THE INVENTION

The inventive systems and methods generally relate to sub-packet error correction in networking and, in particular, to sub-packet error correction for transmission control protocol.

### BACKGROUND

As is known in the art, the Transmission Control Protocol (TCP) provides reliability and flow control for the Internet, serving as one of the essential building blocks of networking technology.

However, TCP's performance over wireless networks can severely degrade due to reliability problems, especially in comparison to performance over wired networks. The degradation of TCP's performance is based at least in part on TCP's assumption that data packet loss in a network is caused by network congestion rather than poor network reliability. TCP may respond to data packet loss by limiting network throughput, a behavior that although may be appropriate for wired networks, can severely (and unnecessarily) limit wireless channel capacity and can fail to properly mitigate reliability problems.

As is also known in the art, numerous approaches have been used to address TCP's performance over wireless networks. These approaches not only attempt to deal with unreliability in wireless networks, but also TCP's incorrect assumption that data packet loss over a network is caused by network congestion. Many of these approaches use data packet forward error correction (FEC) to attempt to provide reliability. For example, Loss Tolerant Transmission Protocol Control (LT-TCP) uses a data packet FEC technique to transmit redundant data packets which the network may use to recover lost data packets. However, many of these approaches provide a coarse granularity of coding rate at the data packet level which can add at least one (and often more) redundant data packet for every data packet, effectively reducing the code rate to at least ½ the code rate without FEC encoding.

### SUMMARY

A sub-packet error correction technique is described for improving Transmission Control Protocol (TCP) performance over lossy networks including segregating TCP data packets received at a first proxy server of a network into sub-packets and encoding the sub-packets using forward error correction (FEC) for transmission to a second proxy server of the network. The sub-packet error correction technique provides control over code rate granularity in a manner that is responsive to network performance and/or criteria including, but not limited to, data packet size and type.

A type of FEC called Random Linear Coding (RLC) may be used to linearly encode the sub-packets using random coefficients. Advantageously, RLC is a rateless FEC (or a so called “erasure code”) that allows near infinite number of redundant sub-packets to be generated so that code rate granularity may be controlled and adjusted based on predetermined criteria. Predetermined criteria may include, but are not limited to, network performance, data packet size and type, tolerable error rates, and/or combinations thereof.

A first proxy server may be used to access the TCP data packets received at a source node, segregate the data packets into sub-packets, and encode the sub-packets using an erasure code. The first proxy server may transmit encoded sub-packets using User Datagram Protocol (UDP) to a second proxy server, where the encoded sub-packets are decoded, reconstructed and forwarded to a destination node.

The first proxy server transmits the encoded sub-packets over a lossy network and may be implemented using a variety of approaches. For example, the first proxy server may be a module that is incorporated into the operating system of a source node that receives the data packet, a module that is incorporated into an application executing on the source node, and/or a module (executing outside the source node) capable of intercepting TCP data packets over a network.

Some embodiments mix data packet FEC with sub-packet FEC to provide code rate granularity responsive to particular TCP data packets and/or operating conditions. For example, these embodiments may use data packet level encoding for smaller data packets (such as control data packets without any user data), and sub-packet level encoding for large data packets to benefit from finer code rate granularity. Code rate may be controlled (i.e., it may be controlled from low to high) based on the severity of data packet loss experienced over a network.

In one aspect, a method of sub-packet error correction includes receiving a data packet, segregating the data packet into sub-packets, and encoding the sub-packets using an erasure code for transmission over a network. In further embodiments, the method includes one or more of the following features: transmitting the encoded sub-packets over the network, receiving the encoded sub-packets, decoding the sub-packets, and combining the decoded sub-packets to reconstruct the data packet; transmitting the sub-packets over a network includes using User Datagram Protocol; segregating the data packet into sub-packets includes segregating the data packet based on predetermined criteria; the predetermined criteria correspond to at least one of a data packet size or a data packet type; the data packet size corresponds to a zero-length data packet; the data packet type includes congestion window reduced (CWR), explicit congestion notification echo (ECE), urgent (URG), acknowledgement (ACK), push function (PSH), reset (RST), synchronize sequence number (SYN), and no more data (FIN); the predetermined criteria correspond to a tolerable data error rate; the data packet is a plurality of data packets, said segregating the data packet into sub-packets being performed on a portion of the plurality of data packets based on the predetermined criteria; storing a copy of the data packet in a cache;

transmitting the encoded sub-packets over the network, and transmitting the cached copy of the data packet based on a detected packet loss over the network; the detected packet loss is associated with an inability to reconstruct the data packet from the encoded sub-packets received over the network; the erasure code uses random linear coding; and a first proxy server receives the data packet from a source node transmitting the data packet to a destination node over the network.

In another aspect, a system for sub-packet error correction includes a first proxy server to receive a data packet, segregate the data packet into sub-packets, and encode the sub-packets using an erasure code for transmission over a network. In further embodiments, the system includes one or more of the following features: a second proxy server to receive the encoded sub-packets from the network, decode the sub-packets, and combine the sub-packets to reconstruct the data packet; the first proxy server transmits the sub-packets over the network using User Datagram Protocol; the first proxy server segregates the data packet into sub-packets based on predetermined criteria; the predetermined criteria correspond to at least one of a data packet size or a data packet type; the data packet size corresponds to a zero-length data packet; the data packet type includes congestion window reduced (CWR), explicit congestion notification echo (ECE), urgent (URG), acknowledgement (ACK), push function (PSH), reset (RST), synchronize sequence number (SYN), and no more data (FIN); the predetermined criteria correspond to a tolerable data error rate; the data packet is a plurality of data packets and the first proxy server segregates a portion of the plurality of data packets based on the predetermined criteria; the first proxy server stores a copy of the data packet in a cache, transmits the encoded sub-packets over the network, and transmits the cached copy of the data packet based on a detected packet loss; the detected packet loss is associated with an inability to reconstruct the data packet from the encoded sub-packets received at the second proxy server over the network; and the erasure code uses random linear coding.

In yet another aspect, a computer-readable medium has encoded thereon software for sub-packet error correction, said software including instructions for receiving a data packet and segregating the data packet into sub-packets, and encoding the sub-packets using an erasure code for transmission over a network. In further embodiments, the software includes one or more of the following features: receiving the encoded sub-packets, decoding the sub-packets and combining the decoded sub-packets to reconstruct the data packet; transmitting the sub-packets over the network including using User Datagram Protocol; segregating the data packet into sub-packets includes segregating the data packet based on predetermined criteria; the predetermined criteria correspond to at least one of a data packet size or a data packet type; the data packet size corresponds to a zero-length data packet; the data packet type includes congestion window reduced (CWR), explicit congestion notification echo (ECE), urgent (URG), acknowledgement (ACK), push function (PSH), reset (RST), synchronize sequence number (SYN), and no more data (FIN); the predetermined criteria correspond to a tolerable data error rate; the data packet is a plurality of data packets, said segregating the data packet into sub-packets being performed on a portion of the plurality of data packets based on the predetermined criteria; storing a copy of the data packet in a cache, transmitting the encoded sub-packets over the network; and transmitting the cached copy of the data packet based on a detected packet loss over the lossy network; the detected packet loss is associated with an inability to reconstruct the data packet from the encoded sub-packets received at a second proxy server over the network; and the erasure code uses random linear coding.

### BRIEF DESCRIPTION OF THE DRAWINGS

The foregoing features of the systems and methods described herein may be more fully understood from the following description of the drawings in which:

FIG. 1 is a pictorial representation of an embodiment of a system for sub-packet error correction;

FIG. 2 is a pictorial representation of a further embodiment of the system for sub-packet error correction of FIG. 1 using random linear coding to encode sub-packets;

FIG. 3A is a pictorial representation of an embodiment of a system for data packet caching and redundancy;

FIG. 3B is a timeline of an exemplary operation of an embodiment of a system for data packet caching and redundancy; and

FIG. 4 is a diagram showing an exemplary hardware and operating environment of a suitable computer for use with embodiments of the inventive systems, methods, and techniques described herein.

### DETAILED DESCRIPTION

Before describing the inventive systems, methods, and techniques, some introductory concepts and terminology are explained. As used herein, the term “data packet” is used to describe a formatted unit of data carried by a network, typically a packet mode computer network. A data packet is known to include at least two types of data: control information and user data. The control information provides information that the network may use to deliver the user data, e.g., source and/or destination addresses, error detection codes such as checksums, and sequencing information. Some data packets include control information in a header and/or a trailer portion of the data packet. User data includes content of the data packets, such as information related to user text, audio, and/or video content. Different communications protocols including, but not limited to, Binary Synchronous Transmission and Ethernet use a variety of methods to distinguish between control information and user data.

The term “lossy network” is used to describe a network that experiences sporadic and/or usually temporary data loss during transmission caused by noise, packet corruption, faulty networking hardware and/or software, and errors in routing, hand-off problems, etc. For example, one type of lossy network includes a wireless radio network which may experience sporadic and/or temporary data loss or interruption of service caused by exposure to electromagnetic effects such as fading, shadowing, and/or multi-pathing. Wireless radio communications may also experience problems due to loss or interruption of service in certain transmission environments. For example, wireless radio communications may be degraded or interrupted in traffic tunnels. Types of wireless radio networks include, but are not limited to, wireless personal area networks which may incorporate Bluetooth™ technology, an open wireless standard for exchanging data over short distances and created originally by Ericsson of Stockholm, Sweden, wireless local area networks including devices which communicate over so called “Wi-Fi” using the 802.11 standard, wireless metropolitan area networks (which may include a WiMAX), wireless wide-area networks, and mobile device networks such as the Global System for Mobile Communication (GSM) and Personal Communications Service (PCS).

Wireless radio carriers may use different technologies to implement and provide wireless network services including, but not limited to, 3^{rd} generation (3G or 3GS), 4^{th} generation (4G), and/or Long Term Evolution (LTE) networks

Lossy networks, however, should not be construed as limited to wireless networks and can include other types of networks such as lossy wired networks including, but not limited to, electrical wiring or cabling. For example, electrical wiring in a home may be prone to electromagnetic interference such as from fluorescent lighting, poor and/or damaged cabling, poor interconnections, environmental noise, etc., causing signal loss and/or degradation.

The term “erasure code” is used to describe a forward error correction (FEC) code that transforms data or a message including k symbols into a longer message (known as a code word) with n symbols. The original message of k symbols can be recovered from a subset of the n symbols. FEC codes are known to have a code rate, which may be calculated as k/n, and a reception efficiency, which may be calculated as k′/k, where k′ denotes the number of symbols required to reconstruct a message.

Furthermore, the term “fountain code” is used to describe a rateless erasure code that does not exhibit a fixed code rate. In a fountain code, a potentially limitless sequence of encoding symbols can be generated from a give set of source symbols. The original source symbols may be recovered from any subset of the encoding symbols of a size equal to or slightly greater than the number of source symbols. Furthermore, a fountain code is optimal if the original k symbols may be recovered from any k encoding symbols. Examples of a fountain code include, but are not limited to, a raptor code, an LT code, and an online code.

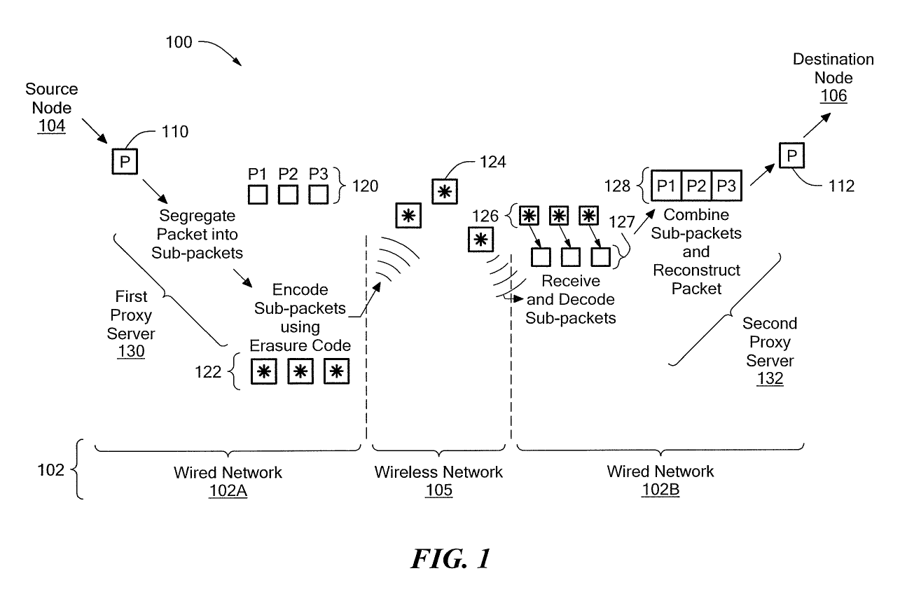

Referring now to FIG. 1, a system 100 for sub-packet error correction includes a first proxy server 130 to receive a data packet 110, segregate the data packet 110 into sub-packets 120, and encode the sub-packets 122 using an erasure code to transmit the sub-packets (an example of which is designated by reference number 124) over a lossy network 105. For clarity in the description and the drawings, three sub-packets (i.e., P1, P2, and P3) are shown. It should, however, be appreciated that although only three packets are shown in FIG. 1, any number of sub-packets may be used to provide sub-packet error correction and it should be understood that an appropriate number of sub-packets may be selected in any particular application.

In a further embodiment, the system 100 includes a second proxy server 132 to receive the encoded sub-packets 126 from the lossy network 105, decode the sub-packets 127, and combine the sub-packets 128 to reconstruct the data packet 112.

In some embodiments, the data packet 110 is received from a source node 104 that processes and formats user data (i.e., generates data packets) for transmission over a network (generally designated by reference numeral 102). For example, a user on a desktop computer may compose and send an email message. An outgoing mail server (the source node 104 in this example) receives the email message and generates data packets for transmission over the network 102.

In embodiments in which the second proxy server 132 reconstructs the data packet 112, the second proxy server 132 may output the reconstructed data packet 112 to a destination node 106 over the network 102. For example, in the previous example involving the email message, an incoming mail server (the destination node 106 in this example) may receive the data packets 112 and output the content to an email recipient on a wireless device.

In some embodiments, segregating the data packet 110 into sub-packets 120 may be accomplished using various methods and protocols below the Transfer Control Protocol (TCP) transport layer of the Internet Protocol. For example, segregating the data packet 110 into sub-packets 120 may occur at the Internet Protocol (IP) layer level during IP fragmentation.

It should be noted that network 102 may include one or more wired networks 102A, 102B and wireless networks 105. In one exemplary networking environment incorporating the inventive systems, methods, and techniques described herein, a content provider establishes data services for users over a network 102 including a first wired network 102A, a lossy wireless network 105, and a second wired network 102B. Here, a content provider node 104 generates data packets 110 associated with data content requested by a user at a destination node 106. The first proxy server 130 receives the data packets 110 from the content provider node 104 over a first wired network 102A, segregates the data packets 110 into sub-packets 120, encodes the sub-packets 122, and transmits the sub-packets 124 over the lossy wireless data network 105. The second proxy server 132 receives the encoded sub-packets 126 from the lossy network 105, decodes the sub-packets 127, and combines the sub-packets 128 to reconstruct the data packets 112. The second proxy server 132 outputs the data packets 112 over a second wired network 102B to the destination 106 where users consume the data content.

In some embodiments, the first proxy server 130 executes on the source node 104. More particularly, the first proxy server 130 may be a low-level module that interacts with or is programmed into the operating system of a source node computer. Here, the first proxy server 130 accesses data packets 110 as they are received and processed before transmission over the lossy network 105. Operating systems such as the Linux operating system may incorporate this type of configuration. Although this configuration requires modifications to the operating system, some performance benefits may be realized over proxy server configurations such as those described below. It should be noted that other configurations may exist, such as executing the first proxy server 130 as a device driver.

In other embodiments, for example, the first proxy server 130 may be an application module (i.e., a module incorporated into an application) that executes on a source node 104 and that interacts with the operating system to receive data packets 110 intended for transmission. In still other embodiments, the first proxy server 130 is external to a source node 104 and may execute as a server module on a standalone computer having access to the network. Here, the first proxy server 130 can be said to intercept and access data packets 110 and encode the data packets 110 as sub-packets 120 before transmission over the lossy network 105. In other words, the first proxy server 130 intercepts the data packets 110, segregates the data packets 110 into sub-packets 120, encodes the sub-packets 122, and transmits the encoded sub-packets 124 to the second proxy server 132 over the lossy network 105. In these embodiments, User Datagram Protocol may be used to transmit the encoded sub-packets 122.

One particular advantage of a stand-alone proxy configuration is that the first proxy server 130 need not require modification of existing applications, server components, and/or operating system components (e.g., TCP-based applications such as file transfer protocol (FTP), and/or other web-based applications).

It should be noted that the second proxy server 132 may be implemented in various configurations such those described above for the first proxy server 130. In some instances, the first proxy server 130 may be implemented in a first configuration, such as an operating system module on the source node 104, and the second proxy server 132 may be implemented in a second configuration, such as a server module on a standalone machine.

In another embodiment, transmitting the sub-packets over a lossy network includes using User Datagram Protocol (UDP). As is known in the art, UDP is a message-based connectionless protocol that does not setup a dedicated end-to-end connection link between a source and a destination node. UDP differs from TCP which is a connection-oriented protocol that requires handshaking to setup end-to-end connection links. UDP is considered unreliable in that, unlike TCP, UDP does not use acknowledgements, retransmissions, or timeouts to determine whether or not a message reaches the destination.

In a further embodiment, segregating the data packet 110 into sub-packets 120 includes segregating the data packet 110 based on predetermined criteria. The predetermined criteria may correspond to at least one of a data packet size or a data packet type. For example, some data packets may be too small to be encoded. For example, zero-length data packets may have no user data in them. Zero-length data packets include certain kinds of control data packets, such as an acknowledgement data packet.

In some embodiments, the predetermined criteria correspond to the data packet type including, but not limited to, congestion window reduced (CWR), explicit congestion notification echo (ECE), urgent (URG), acknowledgement (ACK), push function (PSH), reset (RST), synchronize sequence number (SYN), and no more data (FIN) data packet types.

In other embodiments, the predetermined criteria correspond to a tolerable error rate. In these embodiments, the tolerable error rate may be predefined based on application requirements and/or user preferences, which may include data quality preferences (such as image and/or sound quality). More particularly, the tolerable error rate refers to a tolerable amount of sporadic and/or temporary data loss over a lossy network. For example, in a real-time video application (e.g., a video conferencing application) a tolerable error rate can be in the range of approximately 10-15 percent of transmitted data loss in any given time span, such as one second. In other applications, a user may set the tolerable error rate. For example, a user may set the tolerable error rate to 5%, a rate deemed to be within an acceptable amount of video image degradation due to fading and shadowing (ghosting) of the video image during a video conference.

In other embodiments, the tolerable error rate is a function of the packet erasure rate (PER) experienced on a lossy channel of the network. For example, a relatively high tolerable error rate may correspond to a PER in the range of about 25% packet error loss to as high as about 50%, whereas a relatively low tolerable error rate may correspond to a PER in the range of about 0-5% PER.

In some embodiments, the first proxy server 130 segregates a first data packet and does not segregate a second data packet based on predetermined criteria. For example, in one embodiment, the first proxy server 130 segregates a first data packet that meets or exceeds a predetermined data size (i.e., a relatively large data packet) and does not segregate a second data packet that is less than the predetermined data size (i.e., a relatively small data packet such as a zero-length data packet). Advantageously, this configuration can realize the benefits of sub-packet error correction where needed, desired, or necessary, while reducing and/or eliminating overhead, operational constraints, etc. for small data packets which do not meet predetermined criteria.

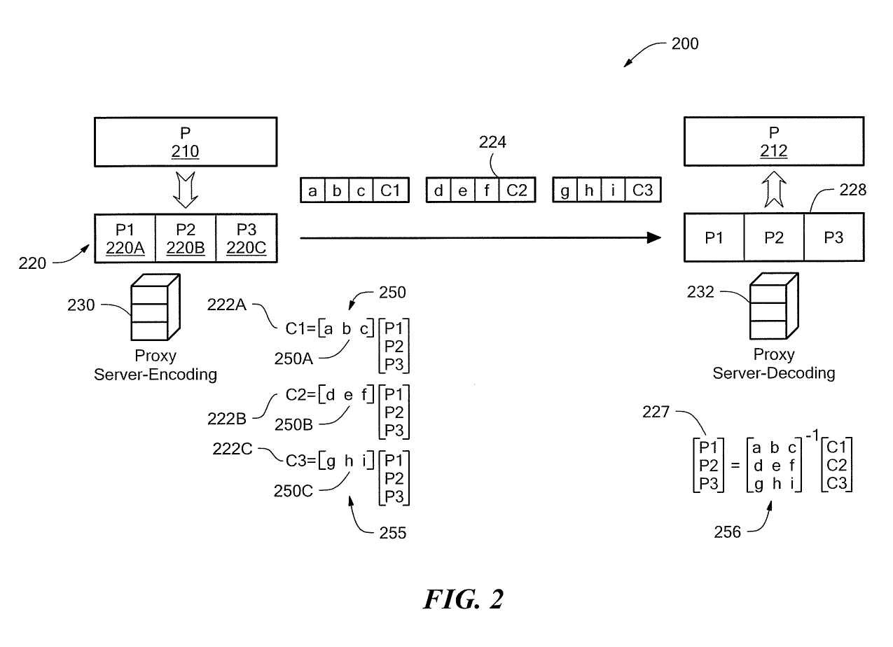

Referring to FIG. 2, a further embodiment of a system 200 for sub-packet error correction includes a first proxy server 230 (as may be similar to first proxy server 130 described in conjunction with FIG. 1) that encodes sub-packets (generally designated by reference numeral 220) using random linear coding (RLC). The first proxy server 230 segregates a data packet 210 into sub-packets 220 and encodes the sub-packets 220 using RLC by randomly selecting coefficients (generally designated by reference numeral 250) for the sub-packets 220. In one particular example shown in FIG. 2, the first proxy server 230 segregates data packet 210 (designated by P) into three sub-packets 220A, 220B, 220C (designated respectively by P1, P2, and P3) and randomly selects a set of three coefficients 250A (designated by a, b, and c), 250B (designated by d, e, and f), 250C (designated by g, h, and i) for each respective sub-packet P1 220A, P2 220B, and P3 220C. For clarity in the description and the drawings, three sub-packets P1, P2, P3 (each with a set of three coefficients (a b c), (d e f), (g h i)) are shown. It should, however, be appreciated that although only three packets are shown in FIG. 2, any number of sub-packets and any number of coefficients for each sub-packet may be used to provide sub-packet error correction and it should be understood that an appropriate number of sub-packets (and sub-packet coefficients) may be selected in any particular application.

The first proxy server 230 performs a matrix computation 255 to generate three RLC encoded sub-packets 222A, 222B, 222C (designated by C1, C2, C3) for transmission to a second proxy server 232 (as may be similar to second proxy server 132 described in conjunction with FIG. 1). The encoded sub-packets C1 222A, C2 222B, and C3 222C are a function of the respective sets of coefficients (a b c), (d e f), (g h i), which may be referred to as the code vectors. In still further embodiments, the respective sets of coefficients (a b c), (d e f), (g h i) are included in the sub-packet headers of the transmitted sub-packets (an example of which is designated by reference numeral 224). Upon receiving the transmitted sub-packets 224, the second proxy server 232 performs a matrix inversion computation 256 to generate a vector 227 including the sub-packets 228 using the encoded sub-packets C1, C2, C3 and sets of coefficients (a b c), (d e f), (g h i). The second proxy server 232 combines the sub-packets 228 to reconstruct the data packet 212.

One particular advantage of sub-packet error correction using rateless erasure codes (such as the above-described RLC) is that data redundancy can be provided at the sub-packet level. More particularly, the first proxy server 232 can use rateless erasures codes to generate a near infinite number of redundant sub-packets for a TCP data packet. This can provide a fine code rate granularity that can be controlled (e.g., based on predetermined criteria described above) to readily adapt to packet loss experienced in a lossy network. In further embodiments, in order to minimize or eliminate the overhead and/or operational constraints that may be associated with RLC (or other types of erasure codes used to encode sub-packets), data packets under a predetermined data packet size threshold are transmitted at the data packet level.

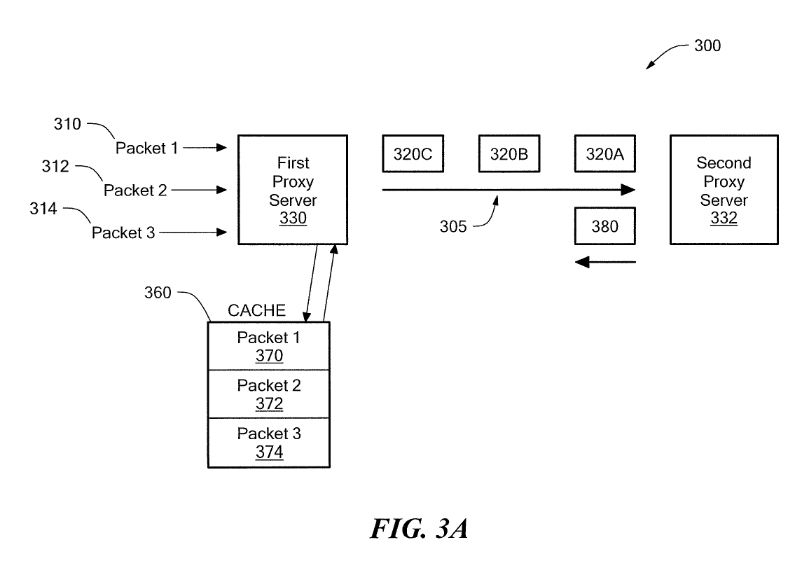

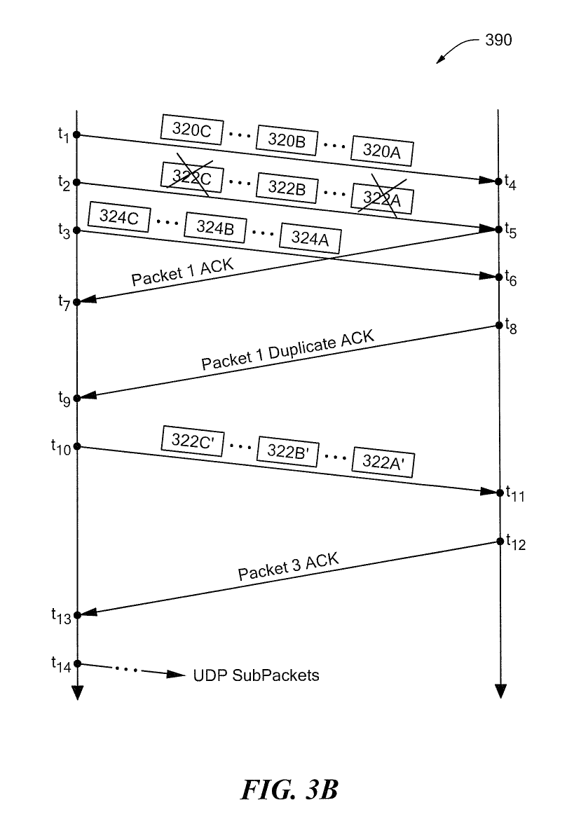

Referring to FIG. 3A, in a further embodiment, a system 300 for sub-packet error correction including data packet caching and redundancy includes a first proxy server 330 that receives a data packet 310 and stores a copy 370 of the data packet in a cache 360. The first proxy server 330 segregates the data packet 310 into sub-packets 320A, 320B, 320C, encodes the sub-packets 320A, 320B, 320C using an erasure code, and transmits the sub-packets 320A, 320B, 320C over a lossy network 305. The first proxy server 330 transmits (or retransmits) the cached copy of data packet 370A based on a detected packet loss. In these embodiments, the first proxy server 330 may transmit the sub-packets 320A, 320B, 320C using UDP.

In a further embodiment, a second proxy server 332 receives the encoded sub-packets 320A, 320B, 320C, decodes the sub-packets 320A, 320B, 320C, and reconstructs the data packet 310. The second proxy server 332 transmits a data packet acknowledgement 380 related to the received data packet 310 (more particularly, to the received sub-packets 320A, 320B, 320C) to the first proxy server 330.

In a further embodiment described herein below with reference to FIG. 3B and again to FIG. 3A, the detected packet loss occurs when the first proxy server 330 to fails to receive data packet acknowledgements for transmitted data packets. Detected packet loss may be associated with an inability of the second proxy server 332 to reconstruct the data packet 310. This may occur if one or more of the transmitted sub-packets 320A, 320B, 320C fail to reach the second proxy server 332 and the second proxy server 332 is unable to reconstruct the data packet 310 from the received sub-packets.

In some embodiments, first proxy server 330 detects data packet loss upon receiving a duplicate acknowledgment of receipt of a particular data packet. The first proxy server 330 prevents the received duplicate acknowledgement from reaching TCP (e.g., TCP at a source node) and handles data packet loss by retransmitting a cached copy of the data packet. This prevents TCP at a source node (as may be similar to source node 104 described in conjunction with FIG. 1) from responding to data packet loss by limiting throughput in based on an inaccurate assumption that data packet loss is due to network congestion rather than poor network reliability.

Referring to FIG. 3B and again to FIG. 3A, a timeline 390 illustrates an exemplary operation of system 300. The first proxy server 330 receives a first TCP data packet 310 (hereinafter referred to as packet 1) and stores a copy 370 of packet 1 in cache 360. The first proxy server 330 also receives a second TCP data packet 312 (hereinafter referred to as packet 2) and a third TCP data packet 314 (hereinafter referred to as packet 3) and stores respective copies 372 and 374 of packet 2 and packet 3 in cache 360.

The first proxy server segregates packet 1 into sub-packets 320A, 320B, 320C, encodes the sub-packets 320A, 320B, 320C using an erasure code, and at time t1 transmits sub-packets 320A, 320B, 320C to second proxy server 332 over a wireless network. The first proxy server also segregates packet 2 into sub-packets 322A, 322B, 322C, encodes the sub-packets 322A, 322B, 322C using an erasure code, and at time t2 transmits sub-packets 322A, 322B, 322C to second proxy server 332 over the wireless network and segregates packet 3 into sub-packets 324A, 324B, 324C, encodes the sub-packets 324A, 324B, 324C using an erasure code, and at time t3 transmits sub-packets 324A, 324B, 324C to second proxy server 332 over the wireless network.

At time t4, the second proxy server receives sub-packets 320A, 320B, 320C decodes the sub-packets and reconstructs data packet 310, and at time t5 the second proxy server transmits an acknowledgement (packet 1 ACK) indicating it has received packet 1. As can be seen in FIG. 3B, the second proxy server 332 fails to receive one or more of the sub-packets 322A, 322B, 322C. More particularly, the second proxy server 332 fails to receive sub-packet 322A and 322C (designed by the “X” through the sub-packets). As described above with reference to lossy networks (and more particularly, to lossy wireless networks), there are many possible reasons why the sub-packets 322A, 322C may fail to reach the second proxy server 332. For example, the network may be exposed to environmental noise and other types of electromagnetic phenomena that can degrade signal reliability and result in a high packet error rate (and particular, to loss of TCP packet 2).

At time t6, the second proxy server 332 receives sub-packets 324A, 324B, 324C, decodes the sub-packets, and reconstructs packet 3 at time t7, the first proxy server 330 receives a packet 1 acknowledgment from the second proxy server 332. At time t8, the second proxy server 332 transmits a duplicate acknowledgement of receipt of packet 1 (packet 1 DUPLICATE ACK), since the second proxy server 332 fails to receive sub-packets 322A and 322C and, therefore, is unable to reconstruct packet 2 and send a packet 2 acknowledgement. At time t9, the first proxy server receives the duplicate acknowledgement of packet 1 and associates the duplicate acknowledgement with detected data packet loss. In this way, the first proxy server 330 can be said to intercept the duplicate acknowledgment, preventing it from reaching TCP at a source node where, in response, TCP may limit (for example, by throttling) overall data packet throughput over the network.

In response to the duplicate acknowledgement, the first proxy server 330 obtains the copy of packet 2 from the cache 360, segregates packet 2 into sub-packets 322A′, 322B′, 322C′, encodes the sub-packets 322A′, 322B′, 322C′, and at time t10 transmits encoded sub-packets 322A′, 322B′, 322C′. At time t11 the second proxy server receives sub-packets 322A′, 322B′, 322C′ and reconstructs packet 2.

At time t12, the second proxy server 332 transmits an acknowledgement (packet 3 ACK) indicating it has received packet 3 and at time t13 the first proxy server 330 receives the packet 3 acknowledgment. At time t14, the first proxy server continues to transmit sub-packets as it receives further data packets.

It should, however, be appreciated that although only packet 1, packet 2, and packet 3 (along with three sub-packets for each respective packet) are shown in FIGS. 3A and 3B, any number of packets (and respective sub-packets) may be included to provide sub-packet error correction and it should be understood that an appropriate number of packets (and sub-packet) may be selected in any particular application.

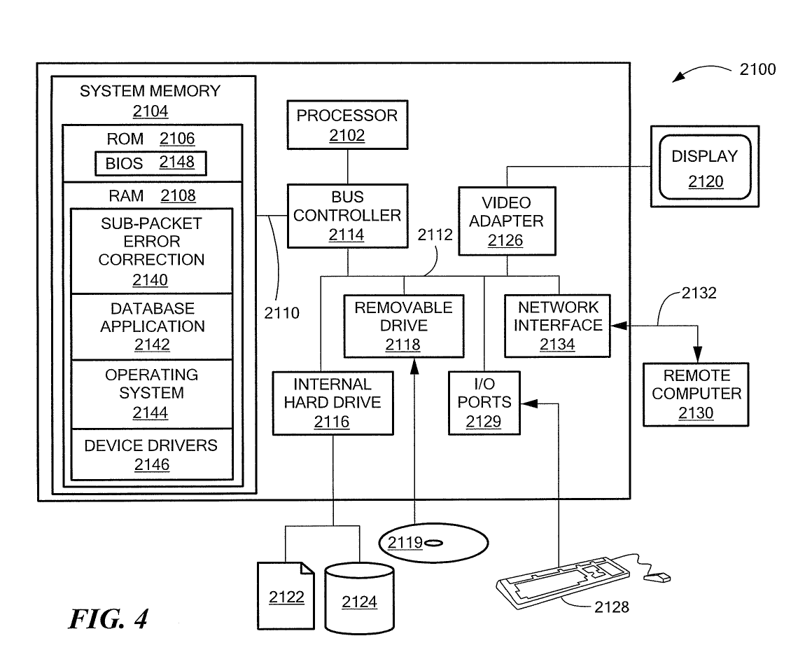

FIG. 4 illustrates a computer 2100 suitable for supporting the operation of an embodiment of the inventive systems, methods, and techniques described herein. The computer 2100 includes a processor 2102, for example, a desktop processor, laptop processor, server and workstation processor, and/or embedded and communications processor. As by way of a non-limiting example, processor 2102 may include an Intel® Core™ i7, i5, or i3 processor manufactured by the Intel Corporation of Santa Clara, Calif. However, it should be understood that the computer 2100 may use other microprocessors. Computer 2100 can represent any server, personal computer, laptop, or even a battery-powered mobile device such as a hand-held personal computer, personal digital assistant, or smart phone.

Computer 2100 includes a system memory 2104 which is connected to the processor 2102 by a system data/address bus 2110. System memory 2104 includes a read-only memory (ROM) 2106 and random access memory (RAM) 2108. The ROM 2106 represents any device that is primarily read-only including electrically erasable programmable read-only memory (EEPROM), flash memory, etc. RAM 2108 represents any random access memory such as Synchronous Dynamic Random Access Memory (SDRAM). The Basic Input/Output System (BIOS) 2148 for the computer 2100 is stored in ROM 2106 and loaded into RAM 2108 upon booting.

Within the computer 2100, input/output (I/O) bus 2112 is connected to the data/address bus 2110 via a bus controller 2114. In one embodiment, the I/O bus 2112 is implemented as a Peripheral Component Interconnect (PCI) bus. The bus controller 2114 examines all signals from the processor 2102 to route signals to the appropriate bus. Signals between processor 2102 and the system memory 2104 are passed through the bus controller 2114. However, signals from the processor 2102 intended for devices other than system memory 2104 are routed to the I/O bus 2112.

Various devices are connected to the I/O bus 2112 including internal hard drive 2116 and removable storage drive 2118 such as a CD-ROM drive used to read a compact disk 2119 or a floppy drive used to read a floppy disk. The internal hard drive 2116 is used to store data, such as in files 2122 and database 2124. Database 2124 includes a structured collection of data, such as a relational database. A display 2120, such as a cathode ray tube (CRT), liquid-crystal display (LCD), etc. is connected to the I/O bus 2112 via a video adapter 2126.

A user enters commands and information into the computer 2100 by using input devices 2128, such as a keyboard and a mouse, which are connected to I/O bus 2112 via I/O ports 2129. Other types of pointing devices that may be used include track balls, joy sticks, and tracking devices suitable for positioning a cursor on a display screen of the display 2120.

Computer 2100 may include a network interface 2134 to connect to a remote computer 2130, an intranet, or the Internet via network 2132. The network 2132 may be a local area network or any other suitable communications network.

Computer-readable modules and applications 2140 and other data are typically stored on memory storage devices, which may include the internal hard drive 2116 or the compact disk 2119, and are copied to the RAM 2108 from the memory storage devices. In one embodiment, computer-readable modules and applications 2140 are stored in ROM 2106 and copied to RAM 2108 for execution, or are directly executed from ROM 2106. In still another embodiment, the computer-readable modules and applications 2140 are stored on external storage devices, for example, a hard drive of an external server computer, and delivered electronically from the external storage devices via network 2132. Data may be stored in memory and/or storage devices. For example, data packets described herein may be stored in memory and/or storage devices and, more particularly, in a cache memory.

The computer-readable modules 2140 may include compiled instructions for implementing data packet and/or sub-packet error correction systems, methods, and techniques described herein. Furthermore, the computer-readable modules may include a first proxy server and/or a second proxy server as described herein. First proxy server may execute on a first processor and second proxy server may execute on a second processor. In some embodiments, the first processor includes a first computer server and the second processor includes a second computer server, the first and second computer servers capable of communication over the network 2132.

The computer 2100 may execute a database application 2142, such as Oracle™ database from Oracle Corporation, to model, organize, and query data stored in database 2124. The data may be used by the computer-readable modules and applications 2140 and/or passed over the network 2132 to the remote computer 2130 and other systems.

In general, the operating system 2144 executes computer-readable modules and applications 2140 and carries out instructions issued by the user. For example, when the user wants to execute a computer-readable module 2140, the operating system 2144 interprets the instruction and causes the processor 2102 to load the computer-readable module 2140 into RAM 2108 from memory storage devices. Once the computer-readable module 2140 is loaded into RAM 2108, the processor 2102 can use the computer-readable module 2140 to carry out various instructions. The processor 2102 may also load portions of computer-readable modules and applications 2140 into RAM 2108 as needed. The operating system 2144 uses device drivers 2146 to interface with various devices, including memory storage devices, such as hard drive 2116 and removable storage drive 2118, network interface 2134, I/O ports 2129, video adapter 2126, and printers.

Having described exemplary embodiments of the invention, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

What is claimed is:

1. A method, comprising:
receiving a data packet and segregating the data packet into sub-packets; and
encoding the sub-packets using an erasure code for transmission over a network.

2. The method of claim 1, further comprising:
transmitting the encoded sub-packets over the network;
receiving the encoded sub-packets; and
decoding the sub-packets and combining the decoded sub-packets to reconstruct the data packet.

3. The method of claim 2, wherein transmitting the sub-packets over a network comprises using User Datagram Protocol.

4. The method of claim 1, wherein segregating the data packet into sub-packets comprises segregating the data packet based on predetermined criteria.

5. The method of claim 4, wherein the predetermined criteria correspond to at least one of a data packet size or a data packet type.

6. The method of claim 4, wherein the data packet size corresponds to a zero-length data packet.

7. The method of claim 5, wherein the data packet type includes congestion window reduced (CWR), explicit congestion notification echo (ECE), urgent (URG), acknowledgement (ACK), push function (PSH), reset (RST), synchronize sequence number (SYN), and no more data (FIN).

8. The method of claim 4, wherein the predetermined criteria correspond to a tolerable data error rate.

9. The method of claim 4, wherein the data packet is a plurality of data packets, said segregating the data packet into sub-packets being performed on a portion of the plurality of data packets based on the predetermined criteria.

10. The method of claim 1, further comprising:
storing a copy of the data packet in a cache;
transmitting the encoded sub-packets over the network; and
transmitting the cached copy of the data packet based on a detected packet loss over the network.

11. The method of claim 10, wherein the detected packet loss is associated with an inability to reconstruct the data packet from the received encoded sub-packets over the network.

12. The method of claim 1, wherein a first proxy server receives the data packet from a source node transmitting the data packet to a destination node over the network.

13. The method of claim 1, wherein the erasure code uses random linear coding.

14. A method, comprising:
receiving a data packet at a first proxy server, the first proxy server segregating the data packet into sub-packets and encoding the sub-packets using an erasure code for transmission over a lossy network; and
receiving the encoded sub-packets at a second proxy server, the second proxy server decoding the sub-packets, and combining the decoded sub-packets to reconstruct the data packet.

15. The method of claim 14, further comprising transmitting the sub-packets over the lossy network using User Datagram Protocol.

16. The method of claim 14, wherein segregating the data packet into sub-packets comprises segregating the data packet based on predetermined criteria.

17. The method of claim 16, wherein the predetermined criteria correspond to at least one of a data packet size or a data packet type.

18. The method of claim 17, wherein the data packet size corresponds to a zero-length data packet.

19. The method of claim 17, wherein the data packet type includes congestion window reduced (CWR), explicit congestion notification echo (ECE), urgent (URG), acknowledgement (ACK), push function (PSH), reset (RST), synchronize sequence number (SYN), and no more data (FIN).

20. The method of claim 16, wherein the predetermined criteria correspond to a tolerable data error rate.

21. The method of claim 16, wherein the data packet is a plurality of data packets, said segregating the data packet into sub-packets being performed on a portion of the plurality of data packets based on the predetermined criteria.

22. The method of claim 16, further comprising:
storing a copy of the data packet in a cache;
transmitting the encoded sub-packets over the lossy network; and
transmitting the cached copy of the data packet based on a detected packet loss over the lossy network.

23. The method of claim 22, wherein the detected packet loss is associated with an inability to reconstruct the data packet from the encoded sub-packets received at a second proxy server over the lossy network.

24. The method of claim 14, wherein the erasure code uses random linear coding.

25. The method of claim 14, wherein the first proxy server receives the data packet from a source node transmitting the data packet to a destination node over the lossy network.

26. The method of claim 25, wherein the second proxy server forwards the reconstructed data packet to the destination node.

27. A system, comprising
a first proxy server to receive a data packet, segregate the data packet into sub-packets, and encode the sub-packets using an erasure code for transmission over a lossy network.

28. The system of claim 27, further comprising:
a second proxy server to receive the encoded sub-packets from the lossy network, decode the sub-packets, and combine the sub-packets to reconstruct the data packet.

29. The system of claim 27, wherein the first proxy server transmits the sub-packets over the lossy network using User Datagram Protocol.

30. The system of claim 27, wherein the first proxy server segregates the data packet into sub-packets based on predetermined criteria.

31. The system of claim 30, wherein the predetermined criteria correspond to at least one of a data packet size or a data packet type.

32. The system of claim 31, wherein the data packet size corresponds to a zero-length data packet.

33. The system of claim 31, wherein the data packet type includes congestion window reduced (CWR), explicit congestion notification echo (ECE), urgent (URG), acknowledgement (ACK), push function (PSH), reset (RST), synchronize sequence number (SYN), and no more data (FIN).

34. The system of claim 30, wherein the predetermined criteria correspond to a tolerable data error rate.

35. The system of claim 30, wherein the data packet is a plurality of data packets and the first proxy server segregates a portion of the plurality of data packets based on the predetermined criteria.

36. The system of claim 27, wherein the first proxy server stores a copy of the data packet in a cache, transmits the encoded sub-packets over the lossy network, and transmits the cached copy of the data packet based on a detected packet loss.

37. The system of claim 36, wherein the detected packet loss is associated with an inability to reconstruct the data packet from the encoded sub-packets received at a second proxy server over the lossy network.

38. The system of claim 27, wherein the erasure code uses random linear coding.

39. A computer-readable medium having encoded thereon software for sub-packet error correction, said software comprising instructions for:
receiving a data packet and segregating the data packet into sub-packets; and
encoding the sub-packets using an erasure code for transmission over a network.

40. The computer-readable medium of claim 39, said software further comprising instructions for:
receiving the encoded sub-packets; and
decoding the sub-packets and combining the decoded sub-packets to reconstruct the data packet.

41. The computer-readable medium of claim 39, wherein transmitting the sub-packets over a network comprises using User Datagram Protocol.

42. The computer-readable medium of claim 39, wherein segregating the data packet into sub-packets comprises segregating the data packet based on predetermined criteria.

43. The computer-readable medium of claim 42, wherein the predetermined criteria correspond to at least one of a data packet size or a data packet type.

44. The computer-readable medium of claim 43, wherein the data packet size corresponds to a zero-length data packet.

45. The computer-readable medium of claim 43, wherein the data packet type includes congestion window reduced (CWR), explicit congestion notification echo (ECE), urgent (URG), acknowledgement (ACK), push function (PSH), reset (RST), synchronize sequence number (SYN), and no more data (FIN).

46. The computer-readable medium of claim 42, wherein the predetermined criteria correspond to a tolerable data error rate.

47. The computer-readable medium of claim 39, wherein the data packet is a plurality of data packets, said segregating the data packet into sub-packets being performed on a portion of the plurality of data packets based on the predetermined criteria.

48. The computer-readable medium of claim 39, said software further comprising instructions for:
storing a copy of the data packet in a cache;
transmitting the encoded sub-packets over the network; and
transmitting the cached copy of the data packet over the network based on a detected packet loss over the network.

49. The computer-readable medium of claim 48, wherein the detected packet loss is associated with an inability to reconstruct the data packet from the encoded sub-packets received over the network.

50. The computer-readable medium of claim 39, wherein the erasure code uses random linear coding.
